(19) United States
(12) Patent Application Publication
(10) Pub. No.: US 2015/0083368 A1
(43) Pub. Date: Mar. 26, 2015

(54) DATA CENTER COOLING SYSTEMS AND ASSOCIATED METHODS

(71) Applicant: COOLIT SYSTEMS INC., Calgary (CA)

(72) Inventor: Geoff Sean Lyon, Calgary (CA)

(21) Appl. No.: 14/550,952

(22) Filed: Nov. 22, 2014

Related U.S. Application Data
(63) Continuation-in-part of application No. 13/559,340, filed on Jul. 26, 2012.
Application No. 13/559,340 is a continuation-in-part of application No. 13/401,618, filed on Feb. 21, 2012.
Application No. 13/401,618 is a continuation-in-part of application No. 12/189,476, filed on Aug. 11, 2008, now Pat. No. 8,746,330.
Application No. 12/189,476 is a continuation-in-part of application No. 14/217,080, filed on Mar. 17, 2014.
(60) Provisional application No. 61/908,043, filed on Nov. 23, 2013.
(60) Provisional application No. 61/622,982, filed on Apr. 11, 2012.
(60) Provisional application No. 61/522,247, filed on Aug. 11, 2011.
(60) Provisional application No. 61/512,379, filed on Jul. 27, 2011.
(60) Provisional application No. 60/954,987, filed on Aug. 9, 2007.
(60) Provisional application No. 61/794,698, filed on Mar. 15, 2013.
(60) Provisional application No. 61/793,479, filed on Mar. 15, 2013.
(60) Provisional application No. 61/856,566, filed on Jul. 19, 2013.
(60) Provisional application No. 61/805,418, filed on Mar. 26, 2013.
(60) Provisional application No. 61/889,481, filed on Oct. 10, 2013.
(60) Provisional application No. 61/880,081, filed on Sep. 19, 2013.

(51) Int. Cl. H05K 7/20

(52) U.S. Cl. CPC H05K 7/208
USPC 165/104.14

(57) ABSTRACT

A heat exchanger has a liquid-liquid heat exchange region and a gas-liquid heat exchange portion. The heat exchange can define a continuous liquid flow path through the liquid-liquid heat exchange region and through the gas-liquid heat exchange portion. The continuous flow path can first pass through the liquid-liquid heat exchange region and then through the gas-liquid heat exchange portion. In other embodiments, the continuous flow path first passes through the gas-liquid heat exchange portion and then through the liquid-liquid heat exchange portion. In some embodiments, the heat exchanger includes a plurality of liquid-liquid heat exchange regions and a plurality of air-liquid heat exchange regions juxtaposed therewith relative to the continuous flow path.

### RELATED APPLICATIONS

This application claims priority from and benefit of U.S. Patent Application No. 61/908,043, filed Nov. 23, 2013, U.S. Patent Application No. 61/889,481, filed on Oct. 11, 2013; U.S. Patent Application No. 61/793,479, filed on Mar. 15, 2013; U.S. patent application Ser. No. 13/559,340, filed on Jul. 26, 2012; U.S. Patent Application No. 61/522,247, filed on Aug. 11, 2011; U.S. Patent Application No. 61/512,379, filed on Jul. 27, 2011; U.S. patent application Ser. No. 13/401,618, filed on Feb. 21, 2012; U.S. patent application Ser. No. 12/189,476, filed on Aug. 11, 2008; U.S. Patent Application No. 61/622,982, filed Apr. 11, 2012; U.S. patent application Ser. No. 14/217,080, filed Mar. 17, 2014, U.S. Patent Application No. 61/794,698, filed Mar. 15, 2013; U.S. Patent Application No. 61/880,081, filed Sep. 19, 2013; U.S. Patent Application No. 60/954,987, filed Aug. 9, 2007; U.S. Patent Application No. 61/856,566, filed Jul. 19, 2013; and U.S. Patent Application No. 61/805,418, filed Mar. 26, 2013, which patent applications are hereby incorporated by reference in their entirety, for all purposes.

### BACKGROUND

The innovations and related subject matter disclosed herein (collectively referred to as the “disclosure”) concern systems configured to transfer heat from one fluid to another fluid, and more particularly, but not exclusively, to systems having a modular configuration. Some examples of such systems are described in relation to cooling electronic components, though the disclosed innovations may be used in a variety of other heat-transfer applications. Heat exchanging manifolds suitable for such systems are described as examples of but one of several innovative aspects of disclosed systems.

As cloud-based and other services grow, the number of networked computers and computing environments, including servers, has substantially increased and is expected to continue to grow.

As used herein, the term “server” generally refers to a computing device connected to a computing network and running software configured to receive requests (e.g., a request to access or to store a file, a request to provide computing resources, a request to connect to another client) from client computing devices also connected to the computing network. Such client computing devices can take the form of traditional personal computers, tablets, smartphones, smart watches, as well as any of a variety of known or hereafter developed smart devices, including but not limited to devices within the so-called “internet of things.”

The term “data center” (also sometimes referred to in the art as a “server farm”) loosely refers to a physical location housing one or more servers. In some instances, a data center can simply comprise an unobtrusive corner in a small office. In other instances, a data center can comprise several large, warehouse-sized buildings enclosing tens of thousands of square feet and housing thousands of servers.

Typical commercially-available servers comprise one or more printed circuit boards having a plurality of operable, heat dissipating devices (e.g., integrated electronic components, such as, for example, memory, chipsets, microprocessors, voltage regulators, application specific integrated circuits (ASICs), graphics processors, hard drives, etc.). As used herein, the term “heat dissipater” or “heat dissipating device” refers to any device or component that dissipates waste heat during operation.

Printed circuit boards are commonly housed in an enclosure. Some enclosures have vents configured to direct external air (e.g., from a local environment, as air within a data center) into, through and out of the enclosure. Such air can absorb heat dissipated by the operable components. After exhausting from the enclosure, the heated air usually mixes with the local environment (e.g., air in the data center) and a conditioner (e.g., a computer room air conditioner, or CRAC) cools the heated local environment, typically consuming large amounts of energy in the process. Other servers are sealed, or otherwise significantly inhibit introduction of air from outside the server into the server.

In general, higher performance server components dissipate correspondingly more power (i.e., energy per unit of time). However, the rate at which conventional cooling systems can suitably remove heat from the various operable devices corresponds, in part, to the extent of air conditioning available from the data center or other facility, as well as the level of power dissipated by adjacent components and servers. For example, the temperature of an air stream entering a server in such a data center can be influenced by the level of power dissipated by, and proximity of, adjacent servers, as well as the temperature of the air entering the data center (or, conversely, the rate at which heat is extracted from the air within the data center).

Some relatively higher performance server components dissipate correspondingly more power. Accordingly, many heat exchangers for removing heat dissipated by such components have been proposed. As but one example, modular device-to-liquid heat exchangers have been proposed, as in U.S. patent application Ser. No. 12/189,476, and related applications.

Some data centers provide conditioned heat transfer media to racks and/or servers therein. For example, some data centers provide relatively lower-temperature air, water, or other working fluid suitable for use in absorbing and removing waste heat from a computing environment, computing installation, or computing facility.

Some proposed systems for transferring heat from heat dissipaters (e.g., within a server) to an environment have been expensive and/or difficult to implement. For example, some systems have been configured to circulate facility water into each server within a rack (or other enclosure). However, as cooling system demands evolve over time, some future servers might be incompatible with water connections provided by some facilities, possibly limiting adoption of new generations of servers. Other deficiencies of proposed systems include increased part counts and assembly costs.

In general, a lower air temperature in a data center allows each server component cooled by an air flow to dissipate a higher power, and thus allows each server to operate at a correspondingly higher level of performance. Consequently, data centers have traditionally used sophisticated air conditioning systems (e.g., chillers, vapor-cycle refrigeration) to cool the air (e.g., to about 65° F.) within the data center to achieve a desired degree of cooling (e.g., corresponding to a desired performance level). Some data centers provide chilled water systems for removing heat from the air within a data center. However, rejecting heat absorbed by air in a data center using sophisticated air conditioning systems, including conventional chilled water systems, consumes high levels of power, and is costly.

In general, heat dissipating components spaced from each other (e.g., a lower heat density) can be more easily cooled than the same components placed in close relation to each other (e.g., a higher heat density). Consequently, data centers have also compensated for increased power dissipation (corresponding to increased server performance) by increasing spacing between adjacent servers. Nonetheless, relatively larger spacing between adjacent servers reduces the number of servers in (and thus the computational capacity of) the data center compared to relatively smaller spacing between adjacent servers.

Therefore, there exists a need for effective and low-cost cooling systems for cooling electronic components, such as, for example, an array of rack mounted servers within a data center, or several arrays of servers within one or among several data centers. There also remains a need for heat-transfer systems associated with computing installations or computing facilities to be compatible with commercially available heat exchangers (e.g., modular device-to-liquid heat exchangers) suitable for use with computing environments, such as, for example, servers. A need remains for facility systems configured to remove heat from one or more servers within a given array of servers. In particular, but not exclusively, there remains a need for reliable cooling systems configured to transfer heat from one or more arrays of servers to a facility heat-transfer medium. A need also remains for such cooling systems to be modular. Such systems should be easy to assemble. A need also remains for efficiently removing heat from air within a data center or an array of servers.

### SUMMARY

Some innovations disclosed herein overcome problems in the prior art and address one or more of the aforementioned or other needs, and pertain generally to modular heat-transfer systems suitable for use in removing waste heat from a computing environment, computing installation, and/or computing facility. More particularly, but not exclusively, some innovations pertain to modular components capable of being assembled into such systems. For example, some disclosed innovations pertain to heat exchanging manifolds configured to thermally couple a facility-provided heat-transfer medium with one or more heat exchange elements in one or more corresponding arrays of servers. Other innovations pertain to modular heat-transfer systems incorporating such heat exchanging manifolds.

Other disclosed innovations pertain to heat exchangers configured to exchange energy in the form of heat between a gas and a liquid (or a saturated mixture thereof). In some embodiments, a heat exchanging manifold can be fluidly coupled to such a heat exchanger. For example, a portion of a fluid circuit configured to couple to a facility water supply can include a heat exchanging manifold configured to exchange heat between a facility-supplied working fluid (e.g., a facility water supply, facility refrigerant, or another facility-supplied coolant, whether in a liquid phase, a gaseous phase, or a saturated mixture thereof) and one or more other liquids. Although particular examples herein are described in relation to facility-supplied water, those of ordinary skill in the art following a review of this disclosure will understand and appreciate that facility-supplied refrigerant or other coolant can be substituted for such facility-supplied water.

Facility water supply can be fluidly isolated from and thermally coupled to at least one of the one or more other liquids. As well, the water supply can be fluidly coupled to a heat exchanger configured to exchange energy in the form of heat between a gas and the facility water. In a particular example, the facility water can be cooled (or chilled) facility water, and the gas can be a stream of air heated by one or more heat dissipaters. As noted above, in other particular embodiments, the facility-supplied working fluid can be a facility supplied refrigerant.

The one or more other liquids can include a coolant or other heat exchange medium directed through a device-to-liquid heat exchanger to absorb waste heat from a heat dissipater and to carry the waste heat to the liquid-to-liquid heat exchanger, where the waste heat is rejected from the one or more other fluids to the cool flow of facility-supplied working fluid.

Still other disclosed innovations pertain to methods of and apparatus configured to facilitate exchanging heat between a first heat-transfer medium and a second heat-transfer medium. And, still other disclosed innovations pertain to cooling systems for data centers or other computing installations and computing facilities. In a general sense, some disclosed innovations relate to module and system configurations that eliminate one or more components from conventional systems while retaining one or more of each eliminated component's respective functions.

In some respects, a heat exchanging manifold can have a heat exchange chamber having a plurality of inlets configured to receive a working fluid of a first fluid circuit and a plurality of outlets configured to discharge the working fluid of the first fluid circuit. An inlet manifold can be configured to receive a working fluid of a second fluid circuit. The working fluid of the second fluid circuit can comprise a liquid, a mixture of different liquids, or a saturated mixture of liquid and gas phase (whether of a single substance or a mixture of different substances).

The inlet manifold can be fluidly isolated from the heat exchange chamber. In context of the working fluid of the second fluid circuit being a refrigerant, the heat exchange chamber sometimes might be referred to in the art as an evaporator, at least with respect to the second fluid circuit. A plurality of heat transfer channels can extend through the heat exchange chamber and fluidly couple to the inlet manifold. With such an arrangement, the working fluid from the second fluid circuit and the working fluid from the first fluid circuit can be thermally coupled with each other. An outlet manifold can fluidly couple to the plurality of heat transfer channels such that the outlet manifold is configured to discharge the working fluid of the second fluid circuit. The inlet manifold can be configured to divide an incoming flow of the working fluid of the second fluid circuit into first and second flow paths having opposed bulk flow directions. The heat exchange chamber can be a first heat exchange chamber, and the heat exchanging manifold can have a second heat exchange chamber having a corresponding second plurality of inlets configured to receive a working fluid of a first fluid circuit. A plurality of outlets from the second heat exchange chamber can be configured to discharge the working fluid of the first fluid circuit. The second heat exchange chamber can be positioned opposite the first heat exchange chamber relative to the inlet manifold.

The plurality of heat transfer channels extending through the first heat exchange chamber can be a first plurality of heat transfer channels. The heat exchanging manifold can also have a second plurality of heat transfer channels extending through the second heat exchange chamber and fluidly coupled to the inlet manifold.

Cooling systems for a computing environment are also disclosed. A plurality of heat exchange elements can be configured to facilitate heat transfer from a heat dissipater to a working fluid of a first fluid circuit. Each heat exchange element can have a corresponding inlet and a corresponding outlet. Each heat exchange element can be fluidly coupled to a heat exchanging manifold as described herein. Working fluid from a second fluid circuit can pass through the heat exchanging manifold and absorb heat rejected from the working fluid of the first fluid circuit to cool the working fluid of the first fluid circuit. Some cooling systems have a conditioner configured to reject heat from the working fluid of the second fluid circuit to an environment.

Server cooling systems are disclosed. Such a cooling system can include a liquid-cooled heat sink having an interface configured to thermally couple with a heat dissipating device. A liquid-to-liquid heat exchanger can be fluidly coupled with the liquid-cooled heat sink to receive a heated first working fluid from the liquid-cooled heat sink. The liquid-to-liquid heat exchanger can be further fluidly coupled to a supply of facility working fluid and facilitates heat transfer from the first working fluid to the facility working fluid without allowing the first working fluid and the facility working fluid to mix with each other. The liquid-to-liquid heat exchanger can exhaust the first working fluid toward the liquid-cooled heat sink after heat transfers from the first working fluid to the facility working fluid. An air-to-liquid heat exchanger fluidly can be coupled with the liquid-to-liquid heat exchanger to receive the facility working fluid from or to deliver the facility working fluid to the liquid-to-liquid heat exchanger. The air-to-liquid heat exchanger can be arranged relative to the liquid-cooled heat sink to absorb heat from a stream of air carrying heat associated with the heat dissipating device.

The liquid-cooled heat sink can be a first liquid-cooled heat sink and the heat dissipating device can be a first heat dissipating device. The server cooling system can include a second liquid-cooled heat sink having an interface configured to thermally couple with a second heat dissipating device. The second liquid-cooled heat sink can be fluidly coupled to the liquid-to-liquid heat exchanger in parallel relative to the first liquid-cooled heat sink. The stream of air can be a first stream of air, and the air-to-liquid heat exchanger can be arranged relative to the second liquid-cooled heat sink to absorb heat from a second stream of air isolated from the first stream of air.

One or both of the liquid-to-liquid heat exchanger and the air-to-liquid heat exchanger can include an evaporator with regard to the facility working fluid.

The liquid-cooled heat sink can include a first liquid-cooled heat sink and the heat dissipating device can be a first heat dissipating device. The cooling system can also include a second liquid-cooled heat sink having an interface configured to thermally couple with a second heat dissipating device. The second liquid-cooled heat sink can be fluidly coupled to the liquid-to-liquid heat exchanger in series relative to the first liquid-cooled heat sink. The air-to-liquid heat exchanger can be arranged relative to the first and the second liquid-cooled heat sinks to absorb heat from the stream of air carrying heat associated with the first and the second heat dissipating devices.

The liquid-to-liquid heat exchanger can have a first portion coupled to the first liquid-cooled heat sink and a second portion coupled to the second liquid-cooled heat sink. At least a portion of the air-to-liquid heat exchanger can be fluidly coupled in series between the first portion of the liquid-to-liquid heat exchanger and the second portion of the liquid-to-liquid heat exchanger.

The portion of the air-to-liquid heat exchanger can have a first portion corresponding to the first stream of air and a second portion corresponding to the second stream of air. The first liquid-cooled heat sink, the first portion of the liquid-to-liquid heat exchanger, and the first portion of the air-to-liquid heat exchanger can correspond to a first server unit mountable within a rack. The second liquid-cooled heat sink, the second portion of the liquid-to-liquid heat exchanger, and the second portion of the air-to-liquid heat exchanger can correspond to a second server unit mountable within the rack.

The first and the second portions of the air-to-liquid heat exchanger can be fluidly coupled to each other in series relative to the facility working fluid and between the first and the second portions of the liquid-to-liquid heat exchanger.

The air-to-liquid heat exchanger can have a first portion corresponding to the first stream of air and a second portion corresponding to the second stream of air. At least a portion of the liquid-to-liquid heat exchanger can be fluidly coupled in series between the first portion of the air-to-liquid heat exchanger and the second portion of the air-to-liquid heat exchanger.

The portion of the liquid-to-liquid heat exchanger can have a first portion corresponding to the first liquid-cooled heat sink and a second portion corresponding to the second liquid-cooled heat sink. The first liquid-cooled heat sink, the first portion of the liquid-to-liquid heat exchanger, and the first portion of the air-to-liquid heat exchanger can correspond to a first server unit mountable within a rack, and the second liquid-cooled heat sink, the second portion of the liquid-to-liquid heat exchanger, and the second portion of the air-to-liquid heat exchanger can correspond to a second server unit mountable within the rack.

The first and the second portions of the liquid-to-liquid heat exchanger can be fluidly coupled to each other in series relative to the facility working fluid and between the first and the second portions of the air-to-liquid heat exchanger.

According to some aspects, first and second liquid-cooled heat sinks can each have an interface configured to thermally couple with a respective heat dissipating device to transfer heat from the heat dissipating device to a first working fluid. A heat exchanger can define a continuous flow path for a facility working fluid. The flow path for the facility working fluid can include a plurality of liquid-cooling segments and a plurality of air-cooling segments, each of the liquid-cooling segments corresponding to a liquid-to-liquid heat exchanger portion of the heat exchanger. The liquid-to-liquid heat exchanger can be configured to fluidly couple to the first and the second liquid-cooled heat sinks to facilitate heat transfer between the first working fluid and the facility working fluid without permitting the first working fluid and the facility working fluid to mix with each other. The plurality of air-cooling segments can correspond to an air-to-liquid heat exchanger portion of the heat exchanger. The air-to-liquid heat exchanger portion can be configured to facilitate heat transfer between one or more independent air streams and the facility working fluid. The heat exchanger can also have an inlet configured to receive facility working fluid and an outlet configured to exhaust the facility working fluid, and the continuous flow path can extend between the inlet and the outlet.

The first and the second liquid-cooled heat sinks can constitute a portion of a first fluid circuit configured to absorb heat from a first server unit. The cooling system can also include a second fluid circuit configured to absorb heat from a second server unit, the second fluid circuit having corresponding first and second liquid-cooled heat sinks, each having an interface configured to thermally couple with a respective heat dissipating device to transfer heat from the heat dissipating device to a working fluid in the second fluid circuit. The first and the second liquid-cooled heat sinks can constitute a portion of a first fluid circuit configured to absorb heat from a corresponding server unit and the liquid-to-liquid heat exchanger portion can be a manifold heat exchanger configured to fluidly couple with a plurality of first fluid circuits and to facilitate heat transfer between the facility working fluid and the first working fluid in each of the first fluid circuits without permitting the facility working fluid to mix with the first working fluid in any of the first fluid circuits. The cooling system can include a rack configured to house a plurality of independently operable server units. The rack can define a front face and a rear face, and the front face can be arranged to receive air from a local environment. The cooling system can include a plurality of first fluid circuits, each being configured to absorb heat from a respective one of the plurality of server units. The heat exchanger can be mounted to the rear face of the rack in an arrangement suitable to thermally couple a respective air stream from each of the server units to one or more air-cooling segments in the air-to-liquid portion of the heat exchanger and subsequently to exhaust each air stream to the local environment. Each in the plurality of first fluid circuits can be fluidly coupled to the manifold heat exchanger to thermally couple the first working fluid in each of the first fluid circuits to one or more of the liquid-cooling segments.

The plurality of liquid cooling segments can be fluidly coupled with each other in series and the air-cooling segments can be fluidly coupled with each other in series. One or more of the plurality of liquid-cooling segments can be interleaved with the plurality of air-cooling segments, as indicated in FIG. 5. Alternatively, none of the liquid-cooling segments is interleaved with the plurality of air-cooling segments, as indicated in FIG. 7.

A server cooling system can include a rack configured to house a plurality of independently operable server units, and the rack can defines a front face and a rear face, with the front face being arranged to receive air from a local environment. Each in a plurality of first fluid circuits can correspond to a respective server unit and have first and second liquid-cooled heat sinks defining an interface configured to thermally couple with a respective heat dissipating device within the respective server unit to transfer heat from the heat dissipating device to a first working fluid within the corresponding heat sink. A heat exchanger can define a continuous flow path for a facility working fluid. The flow path for the facility working fluid can define a plurality of liquid-cooling segments corresponding to a liquid-to-liquid heat exchanger portion of the heat exchanger and a plurality of air-cooling segments corresponding to an air-to-liquid heat exchanger portion of the heat exchanger. The heat exchanger can be mounted to the rear face of the rack to thermally couple a respective air stream from each of the server units to the facility liquid within the air-to-liquid portion of the heat exchanger and subsequently to exhaust each air stream to the local environment. Each in the plurality of first fluid circuits can be fluidly coupled to the liquid-to-liquid portion of the heat exchanger to thermally couple the first working fluid in each of the first fluid circuits to the facility working fluid within the liquid-to-liquid portion of the heat exchanger without permitting the first working fluid to mix with the facility working fluid. The heat exchanger can have an inlet to receive facility working fluid and an outlet to exhaust facility working fluid.

One or more of the plurality of liquid-cooling segments can be interleaved with the plurality of air-cooling segments. Alternatively, none of the liquid-cooling segments is interleaved with the plurality of air-cooling segments.

The liquid-to-liquid portion of the heat exchanger can be physically separate from the air-to-liquid portion of the heat exchanger and fluidly coupled thereto with an intervening conduit, as indicated in FIGS. 8 and 9. Alternatively, the liquid-to-liquid portion of the heat exchanger and the air-to-liquid portion of the heat exchanger define a unitary construct, as indicated in FIG. 5.

Other innovative aspects of this disclosure will become readily apparent to those having ordinary skill in the art from a careful review of the following detailed description (and accompanying drawings), wherein various embodiments of disclosed innovations are shown and described by way of illustration. As will be realized, other and different embodiments of modules and systems incorporating the disclosed innovations are possible, and several disclosed details are capable of being modified in various respects, all without departing from the spirit and scope of the principles disclosed herein. For example, the detailed description set forth below in connection with the appended drawings is intended to describe various embodiments of the disclosed innovations by way of example and is not intended to represent the only embodiments contemplated by the inventors. Instead, the detailed description includes specific details for the purpose of providing a comprehensive understanding of the principles disclosed herein. Accordingly the drawings and detailed description are to be regarded as illustrative and not as restrictive in nature.

### BRIEF DESCRIPTION OF THE DRAWINGS

Unless specified otherwise, the accompanying drawings illustrate aspects of the innovative subject matter described herein. Referring to the drawings, wherein like reference numerals indicate similar parts throughout the several views, several examples of systems incorporating aspects of the presently disclosed principles are illustrated by way of example, and not by way of limitation, wherein:

FIG. 1 shows an array of servers in a data center;

FIG. 2 shows a rack of servers from the array of servers shown in FIG. 1;

FIG. 3 shows the rack of servers shown in FIG. 2 and an air-to-liquid heat exchanger configured to facilitate rejection to a relatively lower temperature flow of liquid of heat absorbed by an air stream;

FIG. 4 shows an example of a heat exchanging manifold incorporating an air-to-liquid heat exchanger similar to that shown in FIG. 3;

FIG. 5 shows an example of a heat exchanging manifold as illustrated schematically in FIG. 4 configured to facilitate an exchange of heat between a liquid coolant of a liquid-cooling circuit and a flow of cool facility water, as well as to facilitate an exchange of heat between a stream of air heated by a plurality of heat dissipaters and the flow of cool facility water;

FIG. 6 shows a schematic illustration of the heat exchanging manifold shown in FIG. 5;

FIG. 7 shows an alternative arrangement of a heat exchanging manifold configured to facilitate an exchange of heat between a liquid coolant of a liquid-cooling circuit and a flow of cool facility water, as well as to facilitate an exchange of heat between a stream of air heated by a plurality of heat dissipaters and the flow of cool facility water;

FIG. 8 shows a schematic illustration of the heat exchanging manifold shown in FIG. 7; and

FIG. 9 shows a schematic illustration of an alternative arrangement of a heat exchanging manifold of the type shown in FIGS. 7 and 8.

FIG. 10 shows an example of first and second components fluidly coupled with each other in series.

FIG. 11 shows an example of the first and second components shown in FIG. 1 fluidly coupled with each other in parallel.

### DETAILED DESCRIPTION

The following describes various innovative principles related to module heat-transfer systems by way of reference to specific examples of modular heat-transfer systems, and more particularly but not exclusively, to modular heat-transfer systems configured to cool an array of servers (e.g., in a data center). Nonetheless, one or more of the disclosed principles can be incorporated in various system configurations to achieve any of a variety of corresponding system characteristics. Systems described in relation to particular configurations, applications, or uses, are merely examples of systems incorporating one or more of the innovative principles disclosed herein and are used to illustrate one or more innovative aspects of the disclosed principles.

Thus, heat-transfer systems having attributes that are different from those specific examples discussed herein can embody one or more of the innovative principles, and can be used in applications not described herein in detail, for example, to transfer heat to or from laser components, light-emitting diodes, chemical reactants undergoing a chemical reaction, photovoltaic cells, solar collectors, power electronic components, electronic components other than microprocessors, photonic integrated circuits, and other electronic modules, as well as a variety of other industrial, military and consumer devices now known or hereafter developed. Accordingly, such alternative embodiments also fall within the scope of this disclosure.

### Overview

Following is a description of certain aspects of modular heat-transfer systems configured to transport heat between an array of heat-transfer elements and an environmental heat-transfer coupler, or a conditioner. Some disclosed modular heat-transfer systems are configured to cool a plurality n independently operable servers (or components thereof) and to remove heat dissipated by the servers from a data center or a server room. Other modular heat-transfer systems incorporating disclosed principles can be configured, for example, to heat a solution of chemical reactants undergoing an endothermic chemical reaction, and to warm an associated stream of air (or other fluid).

### EXAMPLE 1

### Data Centers

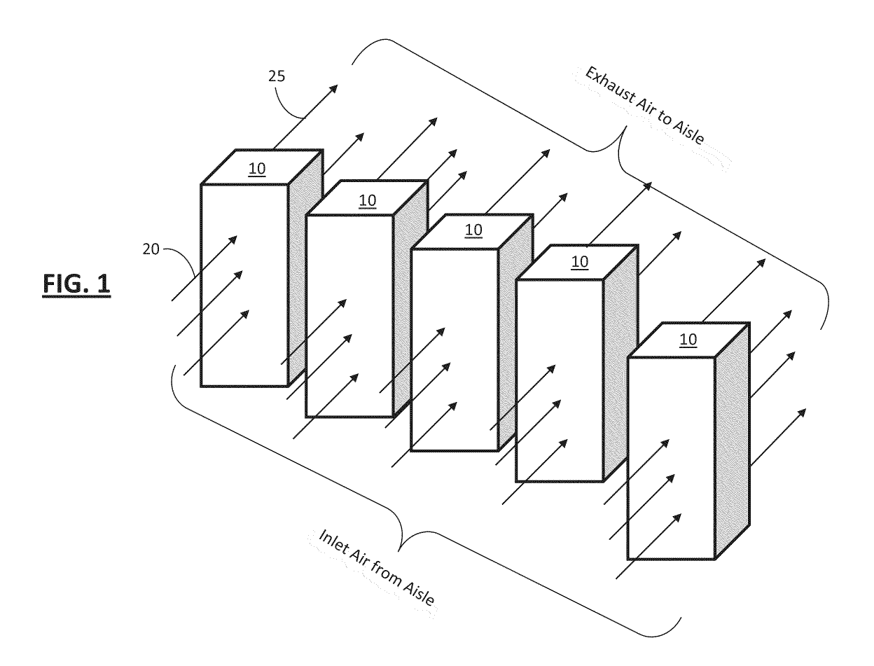

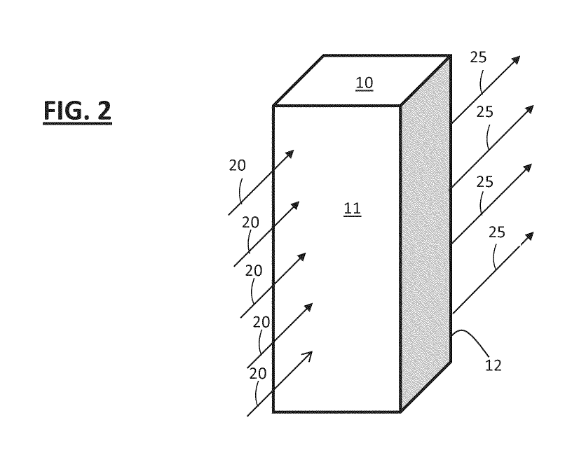

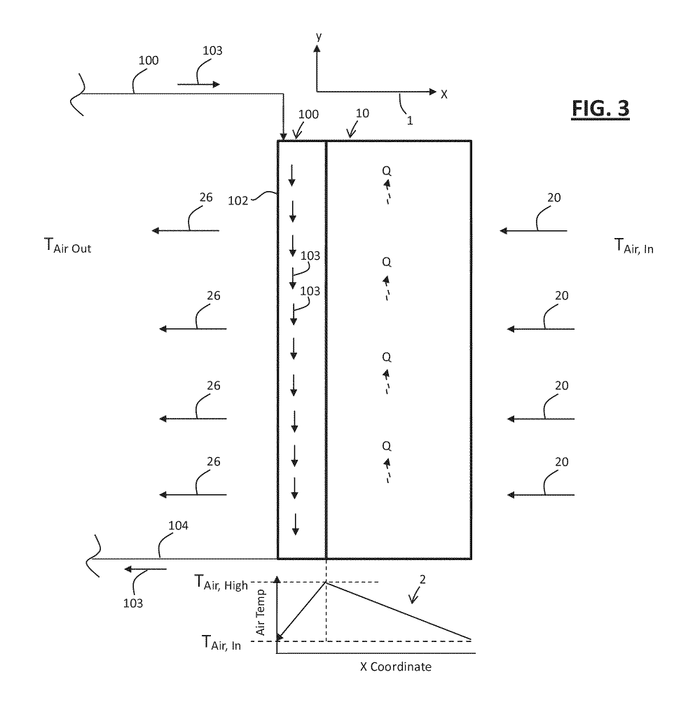

FIG. 1 illustrates a plurality of servers in a data center. In particular, FIG. 1 shows a computing installation having a plurality of server racks 10. Each server rack 10 can be arranged in a similar fashion as the computing installation 10 shown in FIG. 3 in U.S. Patent Application No. 61/889,481, filed on Oct. 11, 2013. Air from the data center can flow through each of the servers, as indicated by the arrows 20 and 25. As shown in FIG. 2, air can enter the rack and the servers through a first face 11 and can exhaust through a second face 12.

Air passing through the servers can absorb waste heat from heat dissipaters in the servers. Several of many possible examples of heat dissipaters typically cooled by air include memory, hard drives, optical drives, power supplies, capacitors, etc.

### EXAMPLE 2

### Gas/Liquid Heat Exchangers

FIG. 3 shows a server rack 10 having a plurality of servers therein. Each of the servers dissipates waste heat \dot{Q}. A portion of the waste heat \dot{Q} is absorbed by air passing through the servers, and a portion of the waste heat \dot{Q} is absorbed by a coolant passing through a liquid cooled heat exchanger, as explained in one or more of the patent applications incorporated herein by reference (e.g., reference number 120a, 120b in FIG. 2 of U.S. patent application Ser. No. 13/351,382).

As depicted by the arrows 20 in FIG. 3, air in the data center (or server room) having a characteristic (e.g., a bulk mean) temperature, T_{air,in}, can flow into the array of servers through a first face 11. While passing through the servers, the air can absorb a portion of the waste heat \dot{Q} and increase in temperature until it reaches a maximum bulk temperature, Tₒᵤₜ, as shown by the plot 2 showing temperature variation of the air along an X-axis coordinate (relative to the coordinate system 1 shown in FIG. 3).

As the heated air exhausts from the array of servers through the second face 12 of the server rack 10, the air can enter a gas-liquid heat exchanger 100 (or in the case of facility-supplied refrigerant, an evaporator). The heat exchanger 100 can be fluidly coupled with a supply of relatively lower temperature water (or other supply of suitable coolant, e.g., refrigerant). The heated air can reject heat to the coolant as the air passes through the heat exchanger 100, cooling the air temperature to a selected temperature.

The cooled air 26 can have a bulk mean temperature, T_{air, out}. As well, the exhaust stream of facility working fluid 104 can have a higher relative temperature than the incoming stream 101 of facility working fluid. (Throughout the rest of this discussion, reference to facility water is made but shall be understood to include alternative working fluids, including refrigerants and other coolants.) The bulk mean temperature, T_{air, out}, can vary according to a temperature of the cooling water entering the heat exchanger 100 through the inlet conduit 101, the flow rate of the water, the flow rate of the air stream, the amount of waste heat dissipated by the servers and absorbed by the air, and the effectiveness (or efficiency) of the heat exchanger 100. In some instances, air exhausting from the heat exchanger 100 can have a substantially similar, if not identical, temperature as the air entering the server rack 10.

A temperature of the incoming flow 103 of facility water can be selected to be slightly greater than a dew-point temperature of the air passing through the servers. By maintaining a temperature of the water above the dew-point of the air, condensation within the heat exchanger 100 from the air can be avoided. If the incoming temperature of facility water exceeds the dew point, other means of managing condensation can be employed.

### EXAMPLE 2

### Integrated Heat Exchangers

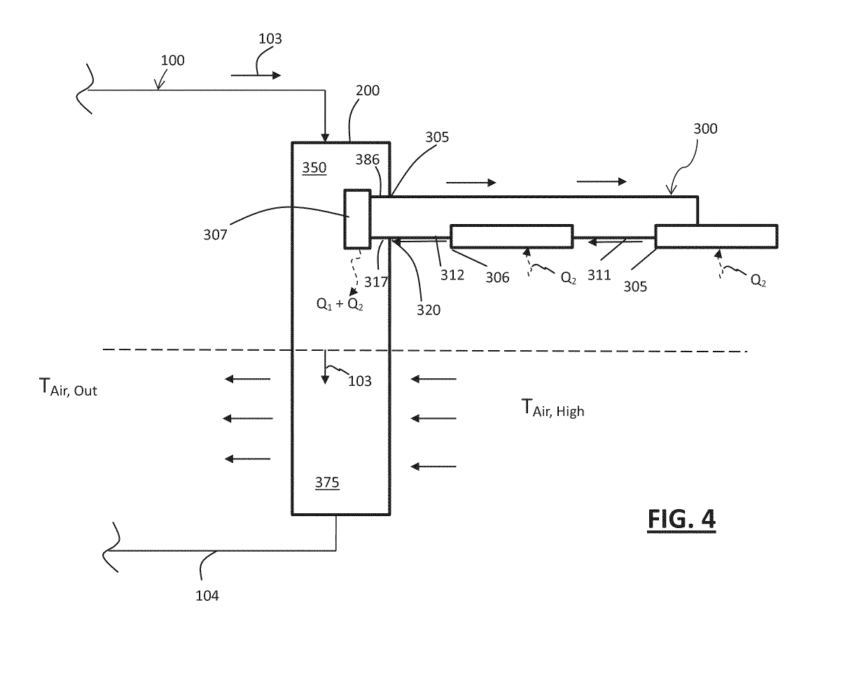

FIG. 4 shows a heat exchanger 200 similar to the heat exchanger 100 shown in FIG. 3, except that a portion 350 of the heat exchanger (or evaporator) 200 is configured as a heat exchanging manifold of the type disclosed in U.S. Patent Application No. 61/889,481 (hereafter, the '481 Application), and a portion 375 of the heat exchanger 200 is configured as an air-liquid heat exchanger (or evaporator) as described in relation to FIG. 3.

As with the heat exchanger 100 (and the heat exchanging manifold 100 in the '481 Application) an incoming flow of cooled facility working fluid can enter the heat exchanger 200 and can absorb heat from a second, fluidly isolated fluid circuit 300 configured to transfer heat from a heat dissipater to the cool flow of facility working fluid (e.g., facility water). As shown in FIG. 4, a first heat dissipater and a second heat dissipater (e.g., first and second processors) can dissipate waste heat \dot{Q}₁ and \dot{Q}₂, respectively. Coolant from the fluidly isolated circuit 300 can absorb the waste heat within a first liquid-cooled heat exchanger (or heat sink) 305 and a second liquid-cooled heat exchanger 306. Coolant can flow from the first heat exchanger 305 through an intermediate fluid coupler (or conduit) 311 and into the second heat exchanger 306. From the second heat exchanger 306, the heated coolant can pass through a liquid-liquid (for example) heat exchange region 307 within the heat exchanger 200. The heated coolant from the second circuit 300 can reject heat to facility working fluid in the heat exchange region 307.

In some embodiments, an inlet 320 and an outlet 315 to the heat exchanger 200 can include quick-disconnect fluid couplers. A fluid coupler (e.g., a conduit 316 and a conduit 317) can extend between the fluid couplers 315, 320 and the heat exchanger 307. Another fluid coupler 310 can return cooled coolant to the first heat exchange module 305.

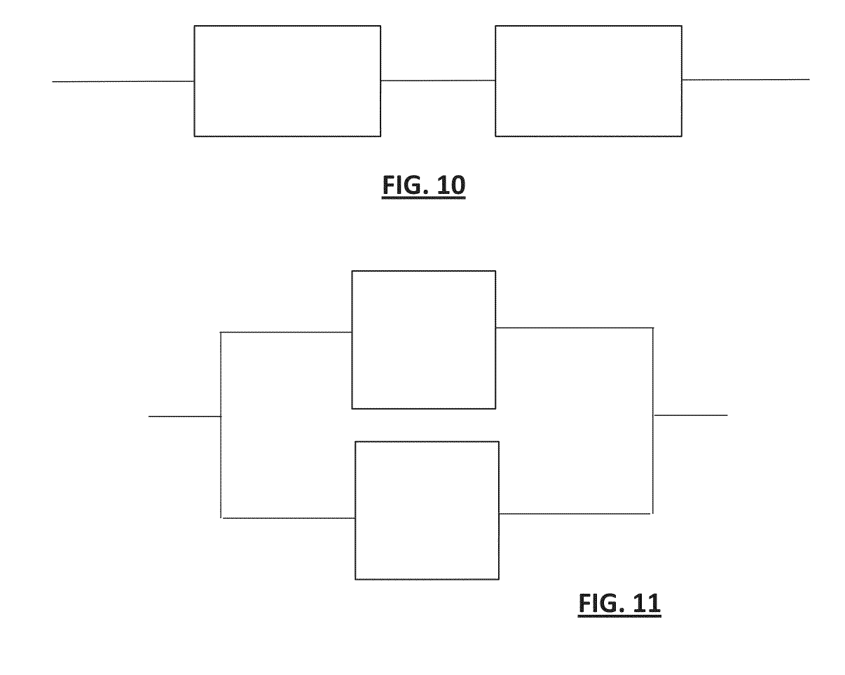

Absorbed waste heat \dot{Q}₁+\dot{Q}₂ can be rejected from the coolant within the fluid circuit 300 to the flow of facility working fluid. After absorbing the waste heat \dot{Q}₁+\dot{Q}₂, the cool (albeit warmed) facility working fluid can pass into an air-liquid heat exchanger region 375, where relatively higher temperature air can reject heat to the facility working fluid. The liquid-to-liquid and the air-to-liquid heat exchange regions 350, 375 are fluidly coupled to each other in series in FIG. 4 (as the components in FIG.10), but they can be fluidly coupled to each other in parallel (as with the components in FIG. 11).

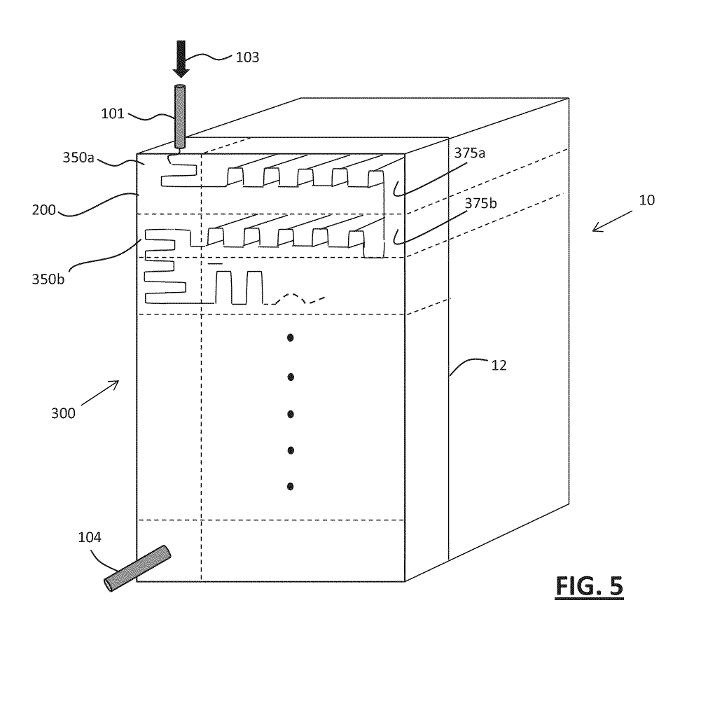

FIG. 5 shows but one possible arrangement of such an integrated, series-coupled heat exchanger. As shown, a heat exchanger 300 can define a first liquid-liquid heat exchange region 350a and a first gas-liquid heat exchange region 375a. The facility working fluid can pass from the first liquid-liquid region 350a and into the first gas-liquid region 375a. In the illustrated embodiment, the facility coolant then passes directly into a second gas-liquid heat-exchange region 375b and then to a second liquid-liquid heat-exchanger region 350b.

Despite that such a serpentine, series-coupled flow path is shown in FIG. 5, an alternative arrangement (not shown) directs the facility coolant through the first liquid-liquid region and the first gas-liquid region, as just described. However, the alternative arrangement can direct the facility coolant from, for example, the first gas-liquid region 375a directly to the second (or another) liquid-liquid heat-exchange region. With the partitioning shown in FIG. 5, a compact, integrated heat exchanger 200 is possible, as in other series- and parallel-coupled arrangements.

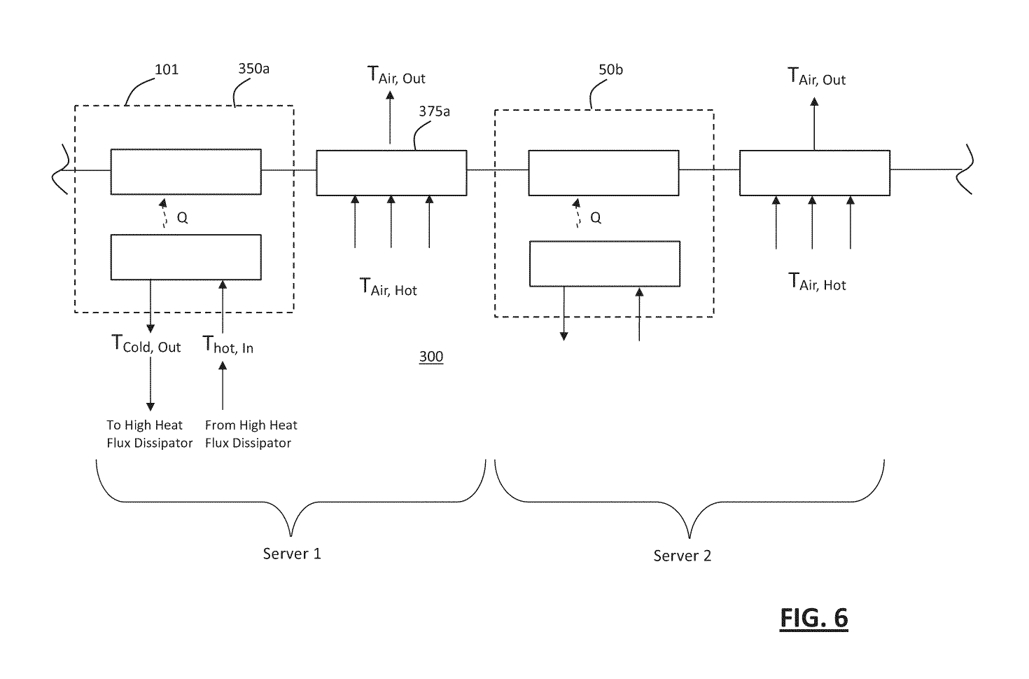

FIG. 6 schematically illustrates the series-coupled flow path taken by the facility coolant through the integrated heat exchanger shown in FIG. 5. Servers 1 and 2 can be fluidly coupled with each other in parallel.

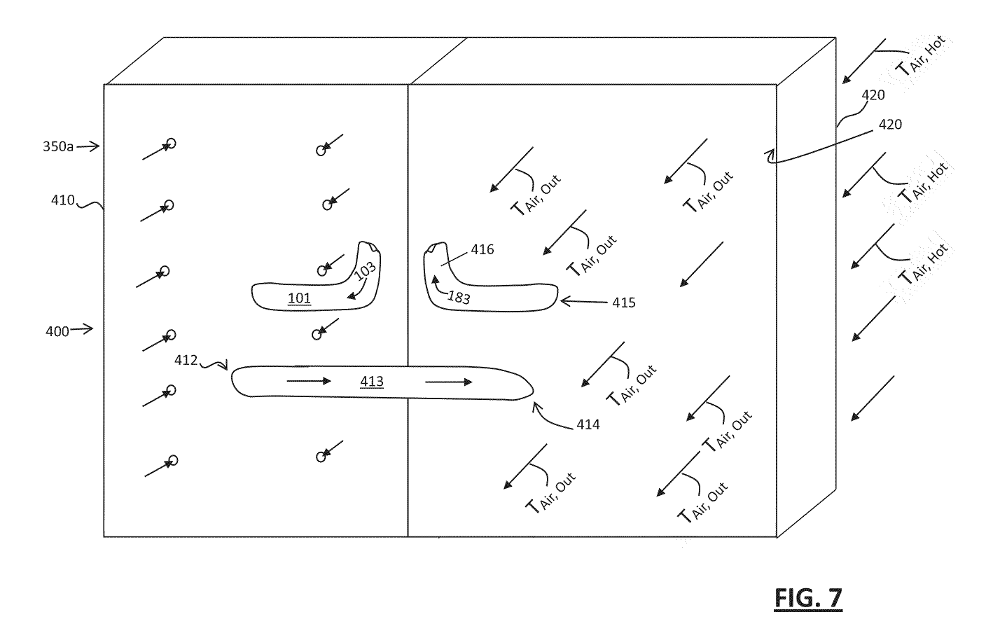

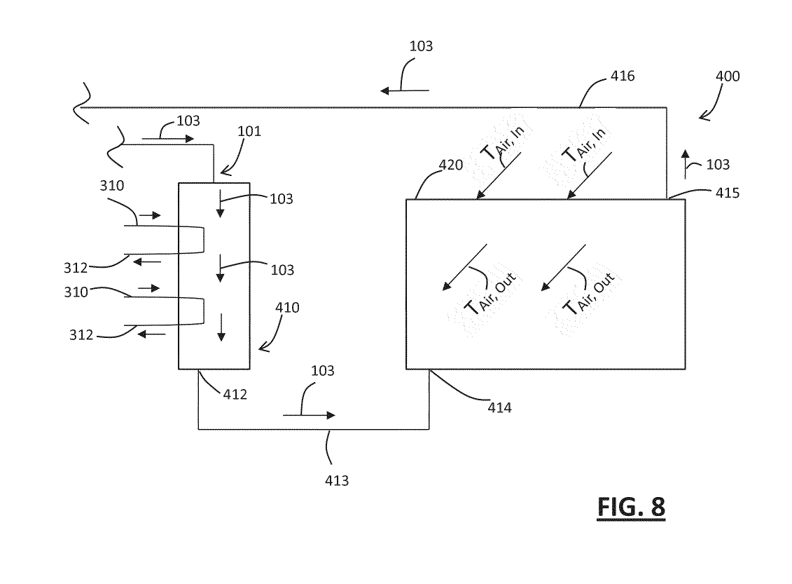

FIG. 7 shows another alternative arrangement of an integrated heat exchanging manifold 400, and FIG. 8 shows the arrangement schematically. In FIG. 7, facility water enters a heat exchanging manifold 410 similar in design to the heat exchanging manifold disclosed in the '481 Application. After absorbing heat from the fluidly isolated cooling circuits 310, 312, the facility coolant exhausts from the manifold portion 410 into a fluid coupler 413 which carries the coolant to an inlet 414 to the air-liquid heat exchange portion 420. The air-liquid heat exchange portion can facilitate an exchange of heat from the heated air stream to the liquid coolant. After absorbing energy from the air stream, the liquid coolant can pass through an outlet 415 into a facility return conduit 416 that carries the facility coolant to a conditioner (e.g., a chiller). Although the heat-exchanging manifold 410 is show, the facility-supplied working fluid can pass through a coolant heat exchanger (e.g. reference number 300 in FIG. 6B in U.S. patent application Ser. No. 13/559,340). Alternatively, the facility supplied working fluid can pass through the air-to-liquid heat exchanger portion (evaporator in some embodiments) before passing through the liquid-to-liquid heat exchanger 410.

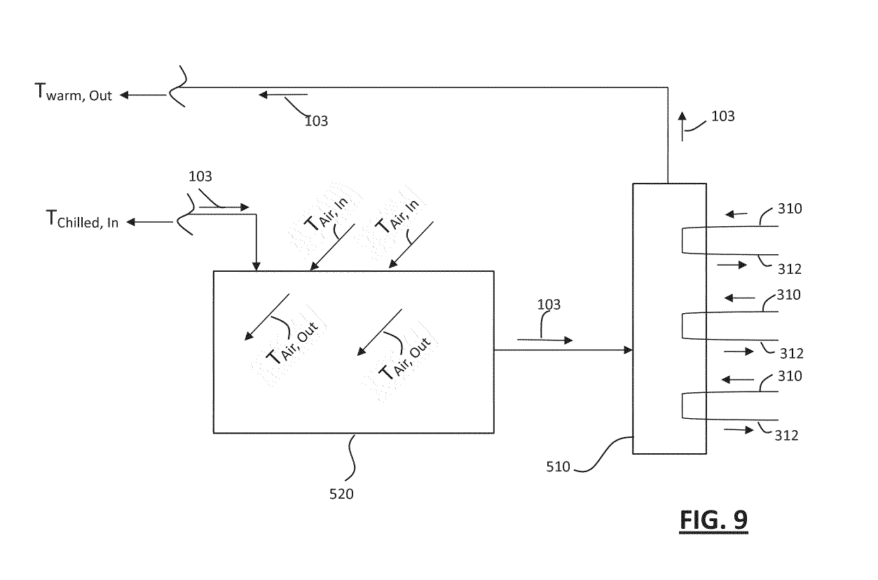

FIG. 9 shows an arrangement 500 similar to the arrangement 400 shown in FIGS. 7 and 8. In the arrangement 500 shown in FIG. 9, the facility coolant first enters the gas-liquid heat exchanger portion 520 and passes to the manifold portion 510 after absorbing heat from the air stream.

### EXAMPLE 3

### Working Fluids

As used herein, “working fluid” means a fluid used for or capable of absorbing heat from a region having a relatively higher temperature, carrying the absorbed heat (as by advection) from the region having a relatively higher temperature to a region having a relatively lower temperature, and rejecting at least a portion of the absorbed heat to the region having a relatively lower temperature.

In some embodiments (e.g., endothermic chemical reactions), the facility-supplied working fluid has a relatively higher temperature than an operable component (e.g., a reaction chamber) corresponding to a given heat-transfer element in the array 100′ (FIG. 4). In other embodiments (e.g., exothermic chemical reactions, servers, lasers), the facility-supplied working fluid has a relatively lower temperature than an operable component (e.g., a reaction chamber, an integrated circuit, a light source).

Some working fluids are sometimes also referred to as a “coolant”. As used herein, “coolant” refers to a working fluid capable of being used in or actually being used in a heat-transfer system configured to maintain a region of a device at or below a selected threshold temperature by absorbing heat from the region. Although many formulations of working fluids are possible, common formulations include distilled water, ethylene glycol, propylene glycol, and mixtures thereof. Other coolants comprise any of a variety of refrigerants, including for example R-134a, some but not all of which require use of compressors to enjoy Joule-Thomson cooling.

### EXAMPLE 4

### Other Exemplary Embodiments

The examples described above generally concern modular heat-transfer systems configured to exchange heat between a region of relatively higher temperature and a region of relatively lower temperature. Other embodiments than those described above in detail are contemplated based on the principles disclosed herein, together with any attendant changes in configurations of the respective apparatus described herein. Incorporating the principles disclosed herein, it is possible to provide a wide variety of modular systems configured to transfer heat. For example, disclosed systems can be used to transfer heat to or from components in a data center, laser components, light-emitting diodes, chemical reactions, photovoltaic cells, solar collectors, and a variety of other industrial, military and consumer devices now known and hereafter developed. Moreover, each example described herein can be used in combination with one or more other examples described herein to arrive at a variety of heat-transfer system arrangements, such as thermoelectric coolers, refrigeration systems, and systems using air cooling of peripheral components, as but several from among many possible examples.

As well, components described herein as being fluidly coupled to each other in series (e.g., FIG. 10) can be coupled to each other in parallel (e.g., FIG. 11) in other embodiments without departing from the scope and spirit of this disclosure.

Directions and references (e.g., up, down, top, bottom, left, right, rearward, forward, etc.) may be used to facilitate discussion of the drawings but are not intended to be limiting. For example, certain terms may be used such as “up,” “down,”, “upper,” “lower,” “horizontal,” “vertical,” “left,” “right,” and the like. Such terms are used, where applicable, to provide some clarity of description when dealing with relative relationships, particularly with respect to the illustrated embodiments. Such terms are not, however, intended to imply absolute relationships, positions, and/or orientations. For example, with respect to an object, an “upper” surface can become a “lower” surface simply by turning the object over. Nevertheless, it is still the same surface and the object remains the same. As used herein, “and/or” means “and” or “or”, as well as “and” and “or.” Moreover, all patent and non-patent literature cited herein is hereby incorporated by references in its entirety for all purposes.

The principles described above in connection with any particular example can be combined with the principles described in connection with any one or more of the other examples. Accordingly, this detailed description shall not be construed in a limiting sense, and following a review of this disclosure, those of ordinary skill in the art will appreciate the wide variety of fluid heat exchange systems that can be devised using the various concepts described herein. Moreover, those of ordinary skill in the art will appreciate that the exemplary embodiments disclosed herein can be adapted to various configurations without departing from the disclosed principles.

The previous description of the disclosed embodiments is provided to enable any person skilled in the art to make or use the disclosed innovations. Various modifications to those embodiments will be readily apparent to those skilled in the art, and the generic principles defined herein may be applied to other embodiments without departing from the spirit or scope of this disclosure. Thus, the claimed inventions are not intended to be limited to the embodiments shown herein, but are to be accorded the full scope consistent with the language of the claims, wherein reference to an element in the singular, such as by use of the article “a” or “an” is not intended to mean “one and only one” unless specifically so stated, but rather “one or more”. All structural and functional equivalents to the elements of the various embodiments described throughout the disclosure that are known or later come to be known to those of ordinary skill in the art are intended to be encompassed by the features described and claimed herein. Moreover, nothing disclosed herein is intended to be dedicated to the public regardless of whether such disclosure is explicitly recited in the claims. No claim element is to be construed under the provisions of 35 USC 112, sixth paragraph, unless the element is expressly recited using the phrase “means for” or “step for”.

Thus, in view of the many possible embodiments to which the disclosed principles can be applied, it should be recognized that the above-described embodiments are only examples and should not be taken as limiting in scope. I therefore reserve to the right to claim any and all combinations of features described herein, including, for example, all that comes within the scope and spirit of the following claims.

1. A cooling system for a server, the cooling system comprising:
a liquid-cooled heat sink having an interface configured to thermally couple with a heat dissipating device;
a liquid-to-liquid heat exchanger fluidly coupled with the liquid-cooled heat sink to receive a heated first working fluid from the liquid-cooled heat sink, wherein the liquid-to-liquid heat exchanger is further fluidly coupled to a supply of facility working fluid and facilitates heat transfer from the first working fluid to the facility working fluid without allowing the first working fluid and the facility working fluid to mix with each other, and wherein the liquid-to-liquid heat exchanger exhausts the first working fluid toward the liquid-cooled heat sink after heat transfers from the first working fluid to the facility working fluid; and
an air-to-liquid heat exchanger fluidly coupled with the liquid-to-liquid heat exchanger to receive the facility working fluid from or to deliver the facility working fluid to the liquid-to-liquid heat exchanger, wherein the air-to-liquid heat exchanger is arranged relative to the liquid-cooled heat sink to absorb heat from a stream of air carrying heat associated with the heat dissipating device.

2. A cooling system according to claim 1, wherein the liquid-cooled heat sink comprises a first liquid-cooled heat sink and the heat dissipating device comprises a first heat dissipating device, the cooling system further comprising a second liquid-cooled heat sink having an interface configured to thermally couple with a second heat dissipating device, wherein the second liquid-cooled heat sink is fluidly coupled to the liquid-to-liquid heat exchanger in parallel relative to the first liquid-cooled heat sink, wherein the stream of air comprises a first stream of air, and wherein the air-to-liquid heat exchanger is arranged relative to the second liquid-cooled heat sink to absorb heat from a second stream of air isolated from the first stream of air.

3. A cooling system according to claim 2, wherein one or both of the liquid-to-liquid heat exchanger and the air-to-liquid heat exchanger comprises an evaporator with regard to the facility working fluid.

4. A cooling system according to claim 1, wherein the liquid-cooled heat sink comprises a first liquid-cooled heat sink and the heat dissipating device comprises a first heat dissipating device, the cooling system further comprising a second liquid-cooled heat sink having an interface configured to thermally couple with a second heat dissipating device, wherein the second liquid-cooled heat sink is fluidly coupled to the liquid-to-liquid heat exchanger in series relative to the first liquid-cooled heat sink, and wherein the air-to-liquid heat exchanger is arranged relative to the first and the second liquid-cooled heat sinks to absorb heat from the stream of air carrying heat associated with the first and the second heat dissipating devices.

5. A cooling system according to claim 4, wherein one or both of the liquid-to-liquid heat exchanger and the air-to-liquid heat exchanger comprises an evaporator with regard to the facility working fluid.

6. A cooling system according to claim 2, wherein the liquid-to-liquid heat exchanger comprises a first portion coupled to the first liquid-cooled heat sink and a second portion coupled to the second liquid-cooled heat sink, and wherein at least a portion of the air-to-liquid heat exchanger is fluidly coupled in series between the first portion of the liquid-to-liquid heat exchanger and the second portion of the liquid-to-liquid heat exchanger.

7. A cooling system according to claim 6, wherein the portion of the air-to-liquid heat exchanger comprises a first portion corresponding to the first stream of air and a second portion corresponding to the second stream of air, and wherein the first liquid-cooled heat sink, the first portion of the liquid-to-liquid heat exchanger, and the first portion of the air-to-liquid heat exchanger correspond to a first server unit mountable within a rack, and the second liquid-cooled heat sink, the second portion of the liquid-to-liquid heat exchanger, and the second portion of the air-to-liquid heat exchanger correspond to a second server unit mountable within the rack.

8. A cooling system according to claim 7, wherein the first and the second portions of the air-to-liquid heat exchanger are fluidly coupled to each other in series relative to the facility working fluid and between the first and the second portions of the liquid-to-liquid heat exchanger.

9. A cooling system according to claim 2, wherein the air-to-liquid heat exchanger comprises a first portion corresponding to the first stream of air and a second portion corresponding to the second stream of air, and wherein at least a portion of the liquid-to-liquid heat exchanger is fluidly coupled in series between the first portion of the air-to-liquid heat exchanger and the second portion of the air-to-liquid heat exchanger.

10. A cooling system according to claim 9, wherein the portion of the liquid-to-liquid heat exchanger comprises a first portion corresponding to the first liquid-cooled heat sink and a second portion corresponding to the second liquid-cooled heat sink, and wherein the first liquid-cooled heat sink, the first portion of the liquid-to-liquid heat exchanger, and the first portion of the air-to-liquid heat exchanger correspond to a first server unit mountable within a rack, and the second liquid-cooled heat sink, the second portion of the liquid-to-liquid heat exchanger, and the second portion of the air-to-liquid heat exchanger correspond to a second server unit mountable within the rack.

11. A cooling system according to claim 7, wherein the first and the second portions of the liquid-to-liquid heat exchanger are fluidly coupled to each other in series relative to the facility working fluid and between the first and the second portions of the air-to-liquid heat exchanger.

12. A cooling system for a server, the cooling system comprising:
first and second liquid-cooled heat sinks, each having an interface configured to thermally couple with a respective heat dissipating device to transfer heat from the heat dissipating device to a first working fluid;
a heat exchanger defining a continuous flow path for a facility working fluid, wherein the flow path for the facility working fluid comprises a plurality of liquid-cooling segments and a plurality of air-cooling segments, wherein each of the liquid-cooling segments corresponds to a liquid-to-liquid heat exchanger portion of the heat exchanger, the liquid-to-liquid heat exchanger being configured to fluidly couple to the first and the second liquid-cooled heat sinks to facilitate heat transfer between the first working fluid and the facility working fluid without permitting the first working fluid and the facility working fluid to mix with each other, wherein the plurality of air-cooling segments corresponds to an air-to-liquid heat exchanger portion of the heat exchanger, the air-to-liquid heat exchanger portion being configured to facilitate heat transfer between one or more independent air streams and the facility working fluid, wherein the heat exchanger further comprises an inlet configured to receive facility working fluid and an outlet configured to exhaust the facility working fluid, and wherein the continuous flow path extends between the inlet and the outlet.

13. A cooling system according to claim 12, wherein the first and the second liquid-cooled heat sinks constitute a portion of a first fluid circuit configured to absorb heat from a first server unit, the cooling system further comprising:
a second fluid circuit configured to absorb heat from a second server unit, the second fluid circuit having corresponding first and second liquid-cooled heat sinks, each having an interface configured to thermally couple with a respective heat dissipating device to transfer heat from the heat dissipating device to a working fluid in the second fluid circuit.

14. A cooling system according to claim 12, wherein the first and the second liquid-cooled heat sinks constitute a portion of a first fluid circuit configured to absorb heat from a corresponding server unit and the liquid-to-liquid heat exchanger portion comprises a manifold heat exchanger configured to fluidly couple with a plurality of first fluid circuits and to facilitate heat transfer between the facility working fluid and the first working fluid in each of the first fluid circuits without permitting the facility working fluid to mix with the first working fluid in any of the first fluid circuits.

15. A cooling system according to claim 14, further comprising:
a rack configured to house a plurality of independently operable server units, wherein the rack defines a front face and a rear face, wherein the front face is arranged to receive air from a local environment; and
a plurality of first fluid circuits, each being configured to absorb heat from a respective one of the plurality of server units; wherein the heat exchanger is mounted to the rear face of the rack in an arrangement suitable to thermally couple a respective air stream from each of the server units to one or more air-cooling segments in the air-to-liquid portion of the heat exchanger and subsequently to exhaust each air stream to the local environment, wherein each in the plurality of first fluid circuits is fluidly coupled to the manifold heat exchanger to thermally couple the first working fluid in each of the first fluid circuits to one or more of the liquid-cooling segments.

16. A cooling system according to claim 14, wherein the plurality of liquid cooling segments are fluidly coupled with each other in series and wherein the air-cooling segments are fluidly coupled with each other in series.

17. A cooling system according to claim 16, wherein one or more of the plurality of liquid-cooling segments is interleaved with the plurality of air-cooling segments.

18. A cooling system according to claim 16 wherein none of the liquid-cooling segments is interleaved with the plurality of air-cooling segments.

19. A cooling system for a server, the cooling system comprising:
a rack configured to house a plurality of independently operable server units, wherein the rack defines a front face and a rear face, wherein the front face is arranged to receive air from a local environment;
a plurality of first fluid circuits, each corresponding to a respective server unit and having first and second liquid-cooled heat sinks defining an interface configured to thermally couple with a respective heat dissipating device within the respective server unit to transfer heat from the heat dissipating device to a first working fluid within the corresponding heat sink; and
a heat exchanger defining a continuous flow path for a facility working fluid, wherein the flow path for the facility working fluid comprises a plurality of liquid-cooling segments corresponding to a liquid-to-liquid heat exchanger portion of the heat exchanger and a plurality of air-cooling segments corresponding to an air-to-liquid heat exchanger portion of the heat exchanger;
wherein the heat exchanger is mounted to the rear face of the rack to thermally couple a respective air stream from each of the server units to the facility liquid within the air-to-liquid portion of the heat exchanger and subsequently to exhaust each air stream to the local environment;
wherein each in the plurality of first fluid circuits is fluidly coupled to the liquid-to-liquid portion of the heat exchanger to thermally couple the first working fluid in each of the first fluid circuits to the facility working fluid within the liquid-to-liquid portion of the heat exchanger without permitting the first working fluid to mix with the facility working fluid; and
wherein the heat exchanger has an inlet to receive facility working fluid and an outlet to exhaust facility working fluid.

20. A cooling system according to claim 19, wherein one or more of the plurality of liquid-cooling segments is interleaved with the plurality of air-cooling segments.

21. A cooling system according to claim 19, wherein none of the liquid-cooling segments is interleaved with the plurality of air-cooling segments.

22. A cooling system according to claim 19, wherein the liquid-to-liquid portion of the heat exchanger is physically separate from the air-to-liquid portion of the heat exchanger and fluidly coupled thereto with an intervening conduit.

23. A cooling system according to claim 19, wherein the liquid-to-liquid portion of the heat exchanger and the air-to-liquid portion of the heat exchanger define a unitary construct.
